(19) United States
(12) Patent Application Publication
(10) Pub. No.: US 2018/0266907 A1
(43) Pub. Date: Sep. 20, 2018

(54) PRESSURE SENSOR, PRESSURE SENSOR MODULE, ELECTRONIC APPARATUS, AND VEHICLE

(71) Applicant: SEIKO EPSON CORPORATION, Tokyo (JP)

(72) Inventors: Masahiro FUJII, Shiojiri-shi (JP); Yusuke MATSUZAWA, Chino-shi (JP)

(73) Assignee: SEIKO EPSON CORPORATION, Tokyo (JP)

(21) Appl. No.: 15/914,260

(22) Filed: Mar. 7, 2018

(30) Foreign Application Priority Data
Mar. 17, 2017 (JP) 2017-053685

(51) Int. Cl. G01L 9/00; H01L 29/84

(52) U.S. Cl. CPC G01L 9/0054; H01L 29/84; G01L 9/0048

(57) ABSTRACT

A pressure sensor includes a substrate which includes a diaphragm that is flexurally deformed by receiving a pressure, a piezoresistive element which is provided in the diaphragm; and a protective film which is provided on one surface side of the diaphragm. The protective film includes a thin section and a thick section which is thicker than the thin section. Further, in a plan view of the substrate, the thin section overlaps with the piezoresistive element, and the thick section overlaps with at least a part of the diaphragm.

### BACKGROUND

### 1. Technical Field

The present invention relates to a pressure sensor, a pressure sensor module, an electronic apparatus, and a vehicle.

### 2. Related Art

There has been known a configuration described in, for example, WO 2010/055734 (Patent Document 1) as a pressure sensor. The pressure sensor described in Patent Document 1 includes a substrate including a diaphragm which is flexurally deformed by receiving a pressure, a piezoresistive element formed on the diaphragm, and a protective film placed on one surface (upper surface) of the substrate, and is configured to detect a pressure by utilizing the change in the resistance value of the piezoresistive element based on the flexure of the diaphragm.

Further, in the pressure sensor described in Patent Document 1, in order to improve the detection sensitivity by making the diaphragm easier to flex, a recessed section is formed in a portion, which overlaps with the entire region of the diaphragm, of the protective film, and the protective film on the diaphragm is made thin. However, according to such a configuration, the mechanical strength of the diaphragm is decreased, and the diaphragm is easily broken. That is, the pressure sensor described in Patent Document 1 has difficulty in achieving both pressure detection sensitivity and mechanical strength.

### SUMMARY

An advantage of some aspects of the invention is to provide a pressure sensor capable of achieving both pressure detection sensitivity and mechanical strength, a pressure sensor module, an electronic apparatus, and a vehicle.

The advantage can be achieved by the following configurations.

A pressure sensor according to an aspect of the invention includes a substrate which includes a diaphragm that is flexurally deformed by receiving a pressure, a piezoresistive element which is provided in the diaphragm, and a protective film which is provided on one surface side of the diaphragm, wherein the protective film includes a thin section, and a thick section which is thicker than the thin section, and in a plan view of the substrate, the thin section overlaps with the piezoresistive element, and the thick section overlaps with at least a part of the diaphragm.

According to this configuration, a pressure sensor capable of achieving both pressure detection sensitivity and mechanical strength is obtained.

In the pressure sensor according to the aspect of the invention, it is preferred that in a plan view of the substrate, the thick section overlaps with at least a part of the outer edge of the diaphragm.

According to this configuration, both pressure detection sensitivity and mechanical strength can be more effectively achieved.

In the pressure sensor according to the aspect of the invention, it is preferred that in a plan view of the substrate, the outer edge of the diaphragm has at least one corner section, and the thick section overlaps with the corner section.

In a case where the outer edge of the diaphragm has a corner section in this manner, a stress is likely to be concentrated particularly on the corner section in the outer edge, and the diaphragm is often broken from the corner section. Therefore, by placing the thick section so as to overlap with the corner section and reinforcing the corner section, the breakage of the diaphragm triggered by stress concentration on the corner section can be suppressed.

In the pressure sensor according to the aspect of the invention, it is preferred that in a plan view of the substrate, the outer edge of the diaphragm has at least two corner sections and a side located between the two corner sections, the thick section overlaps with the respective corner sections, and the thin section overlaps with the side.

According to this configuration, it becomes easy to place the piezoresistive element in the outer edge portion of the diaphragm. Further, the decrease in the pressure detection sensitivity due to the overlapping of the thick section with the piezoresistive element can be effectively suppressed.

In the pressure sensor according to the aspect of the invention, it is preferred that the thick section overlaps with a central portion of the diaphragm.

According to this configuration, a relatively large stress can be generated around the thick section. Therefore, the pressure detection sensitivity can be improved.

In the pressure sensor according to the aspect of the invention, it is preferred that the piezoresistive element is placed in an outer edge portion of the diaphragm.

When the diaphragm is flexurally deformed by receiving a pressure, a large stress is applied particularly to the outer edge portion in the diaphragm, and therefore, by placing the piezoresistive element in the outer edge portion, the pressure detection sensitivity of the pressure sensor is improved.

In the pressure sensor according to the aspect of the invention, it is preferred that the piezoresistive element is also placed in a central portion of the diaphragm.

According to this configuration, the pressure detection sensitivity of the pressure sensor is improved.

In the pressure sensor according to the aspect of the invention, it is preferred that the thin section includes a first insulating film containing silicon oxide and a second insulating film containing silicon nitride.

According to this configuration, by the first insulating film, the interface state of the piezoresistive element is reduced, and the occurrence of noise can be suppressed. Further, by the second insulating film, the sensor section can be protected from water and dust, and the reliability of the pressure sensor can be enhanced.

In the pressure sensor according to the aspect of the invention, it is preferred that the pressure sensor includes a pressure reference chamber placed so as to overlap with the diaphragm in a plan view of the substrate.

According to this configuration, a pressure received by the diaphragm can be detected on the basis of the pressure in the pressure reference chamber, and therefore, the pressure received by the diaphragm can be more accurately detected.

A pressure sensor module according to an aspect of the invention includes the pressure sensor according to the aspect of the invention and a package which houses the pressure sensor.

According to this configuration, the effect of the pressure sensor according to the aspect of the invention can be received, and therefore, a pressure sensor module having high reliability is obtained.

An electronic apparatus according to an aspect of the invention includes the pressure sensor according to the aspect of the invention.

According to this configuration, the effect of the pressure sensor according to the aspect of the invention can be received, and therefore, an electronic apparatus having high reliability is obtained.

A vehicle according to an aspect of the invention includes the pressure sensor according to the aspect of the invention.

According to this configuration, the effect of the pressure sensor according to the aspect of the invention can be received, and therefore, a vehicle having high reliability is obtained.

### BRIEF DESCRIPTION OF THE DRAWINGS

The invention will be described with reference to the accompanying drawings, wherein like numbers reference like elements.

FIG. 1 is a cross-sectional view showing a pressure sensor according to a first embodiment of the invention.

FIG. 2 is a plan view showing a sensor section included in the pressure sensor shown in FIG. 1.

FIG. 3 is a circuit diagram showing a bridge circuit including the sensor section shown in FIG. 2.

FIG. 4 is a plan view showing a protective film included in the pressure sensor shown in FIG. 1.

FIG. 5 is a cross-sectional view showing a variation of the pressure sensor shown in FIG. 1.

FIG. 6 is a flowchart showing a production step of the pressure sensor shown in FIG. 1.

FIG. 7 is a cross-sectional view for illustrating a production method for the pressure sensor shown in FIG. 1.

FIG. 8 is a cross-sectional view for illustrating the production method for the pressure sensor shown in FIG. 1.

FIG. 9 is a cross-sectional view for illustrating the production method for the pressure sensor shown in FIG. 1.

FIG. 10 is a cross-sectional view for illustrating the production method for the pressure sensor shown in FIG. 1.

FIG. 11 is a cross-sectional view for illustrating the production method for the pressure sensor shown in FIG. 1.

FIG. 12 is a cross-sectional view for illustrating the production method for the pressure sensor shown in FIG. 1.

FIG. 13 is a cross-sectional view for illustrating the production method for the pressure sensor shown in FIG. 1.

FIG. 14 is a cross-sectional view for illustrating the production method for the pressure sensor shown in FIG. 1.

FIG. 15 is a cross-sectional view for illustrating the production method for the pressure sensor shown in FIG. 1.

FIG. 16 is a flowchart showing another production step of the pressure sensor shown in FIG. 1.

FIG. 17 is a cross-sectional view showing a pressure sensor according to a second embodiment of the invention.

FIG. 18 is a plan view showing a protective film included in the pressure sensor shown in FIG. 17.

FIG. 19 is a circuit diagram showing a bridge circuit including the sensor section shown in FIG. 18.

FIG. 20 is a cross-sectional view of a pressure sensor module according to a third embodiment of the invention.

FIG. 21 is a plan view of a support substrate included in the pressure sensor module shown in FIG. 20.

FIG. 22 is a perspective view showing an altimeter as an electronic apparatus according to a fourth embodiment of the invention.

FIG. 23 is a front view showing a navigation system as an electronic apparatus according to a fifth embodiment of the invention.

FIG. 24 is a perspective view showing a car as a vehicle according to a sixth embodiment of the invention.

### DESCRIPTION OF EXEMPLARY EMBODIMENTS

Hereinafter, a pressure sensor, a pressure sensor module, an electronic apparatus, and a vehicle according to the invention will be described in detail based on embodiments shown in the accompanying drawings.

### First Embodiment

First, a pressure sensor according to a first embodiment of the invention will be described.

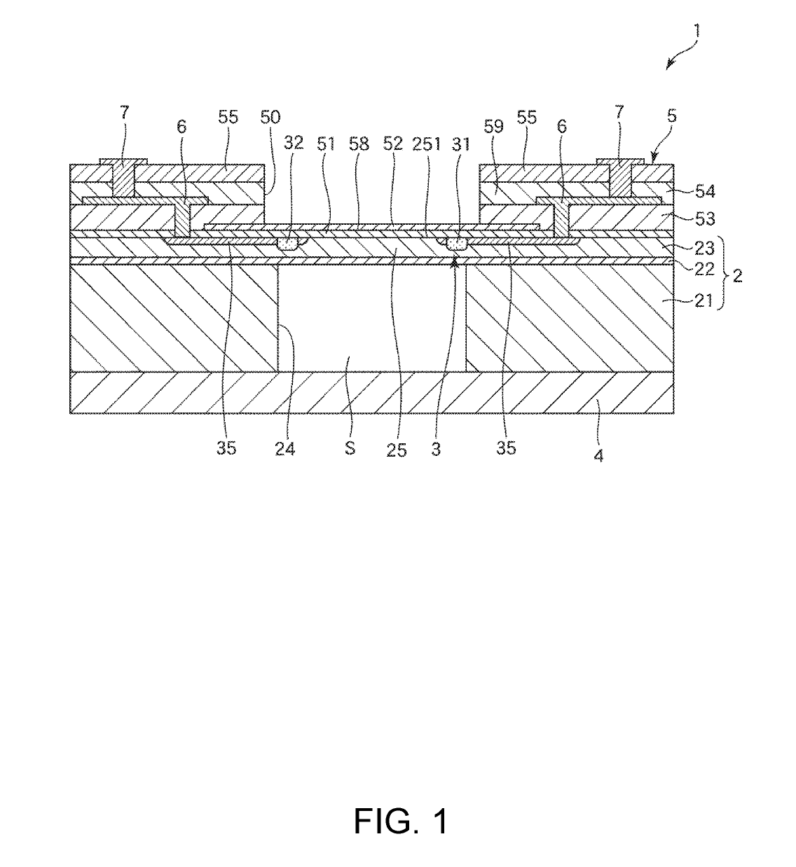

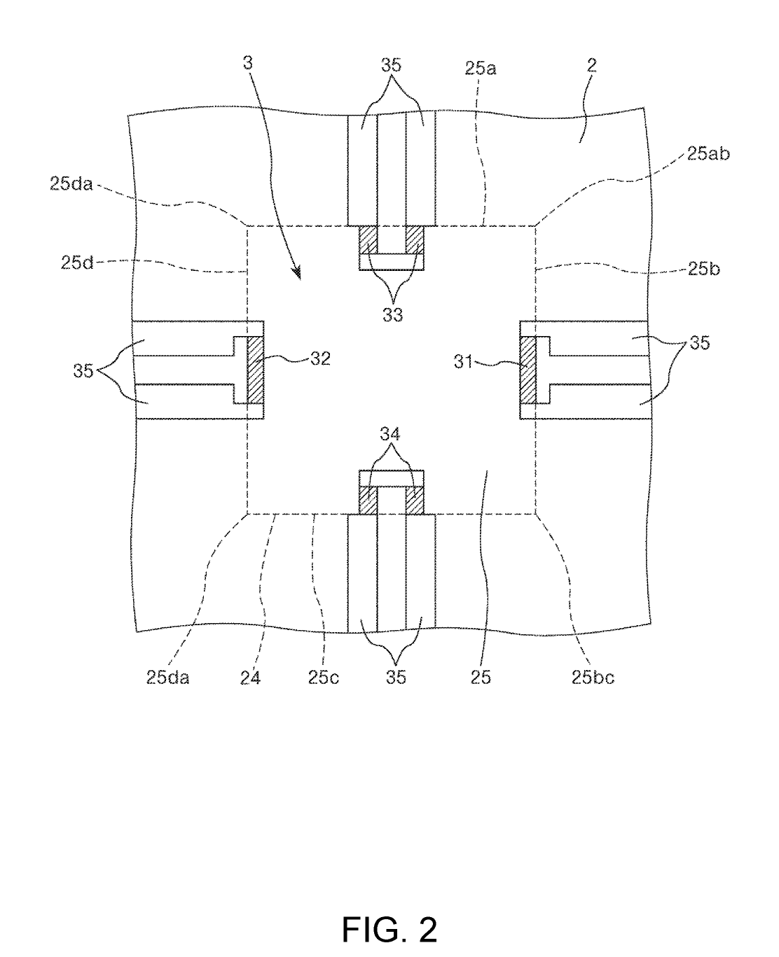

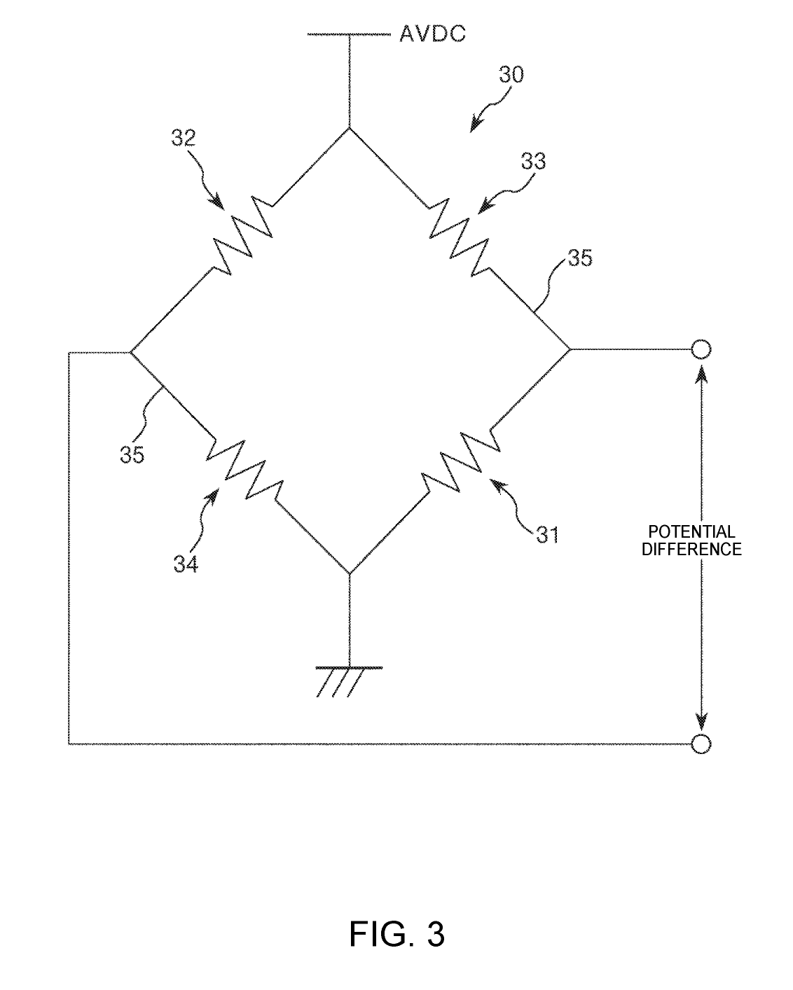

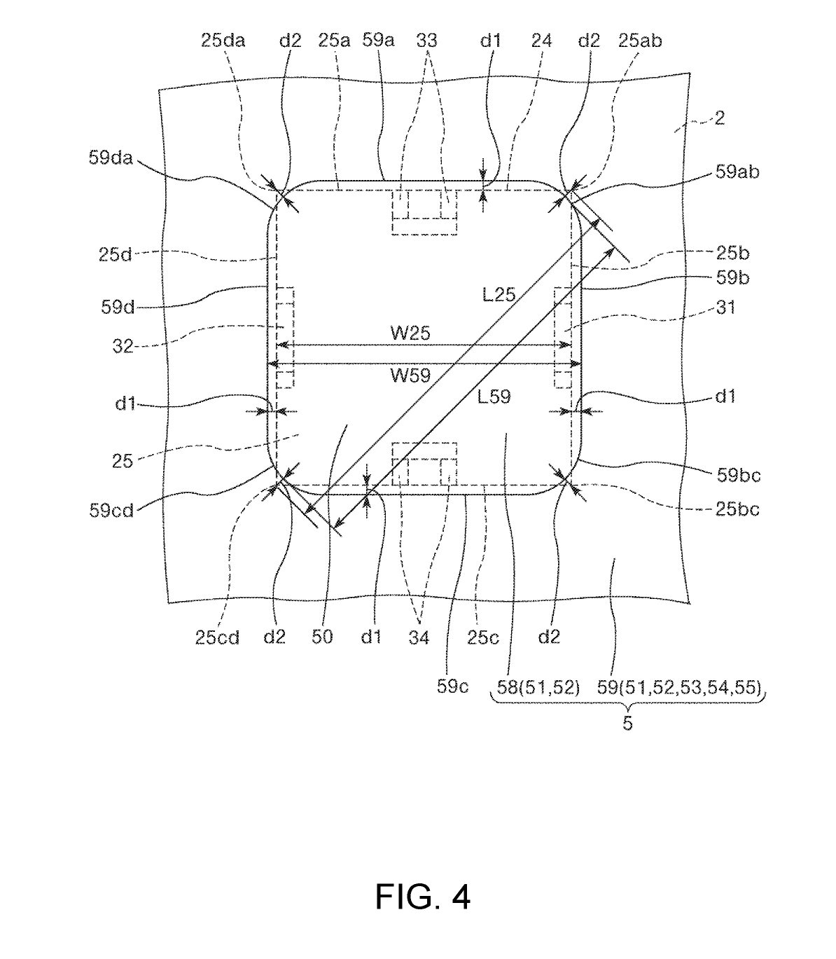

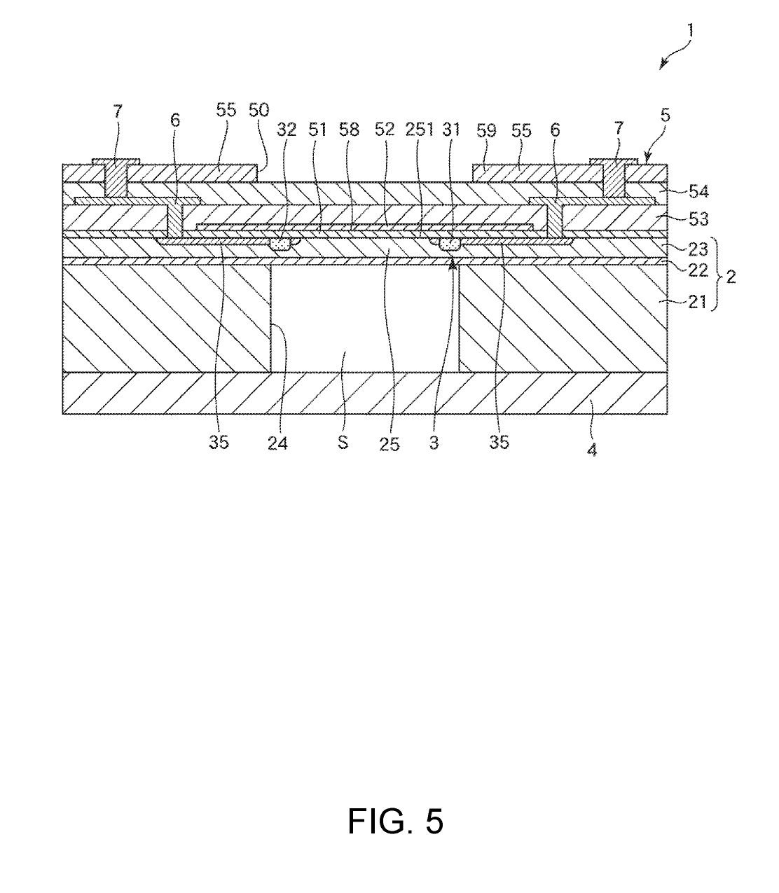

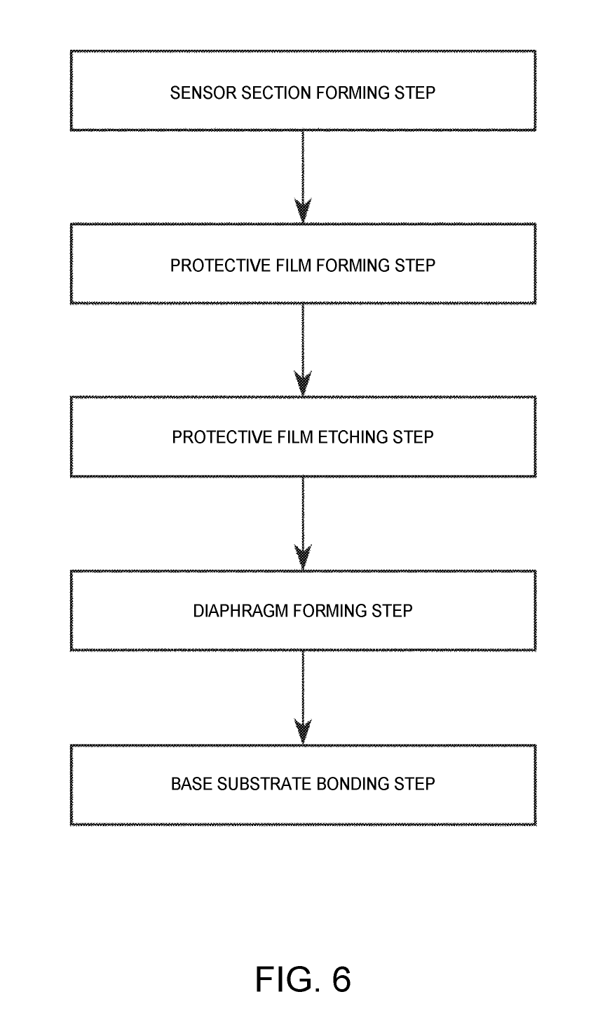

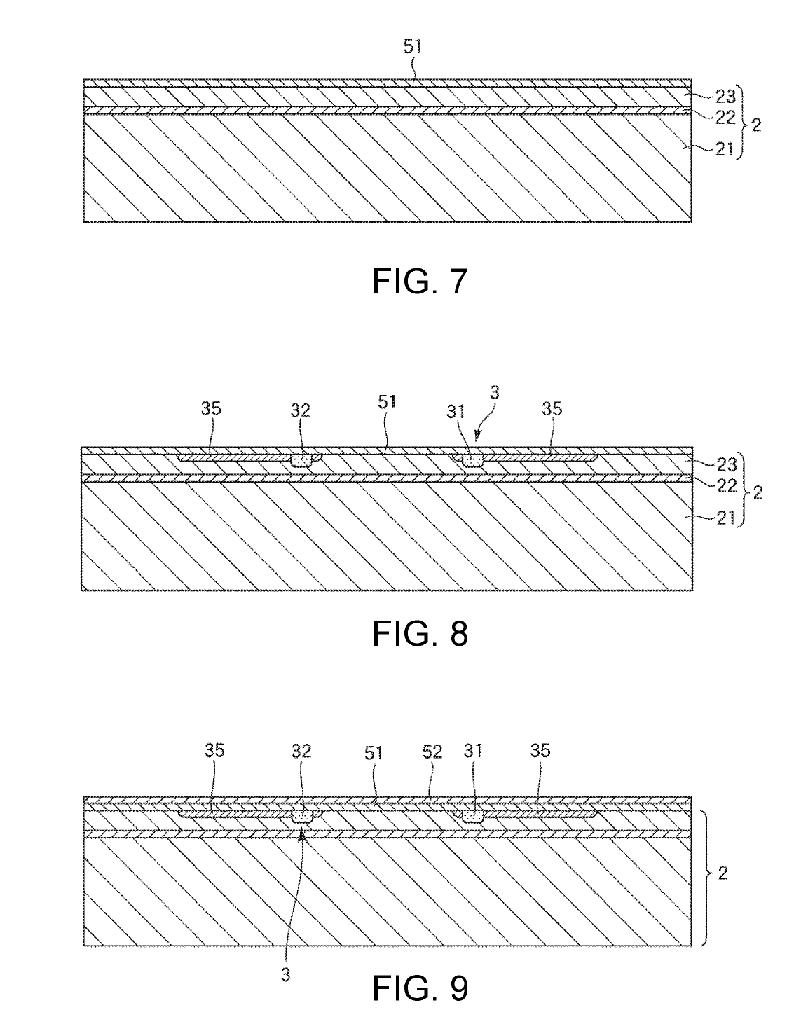

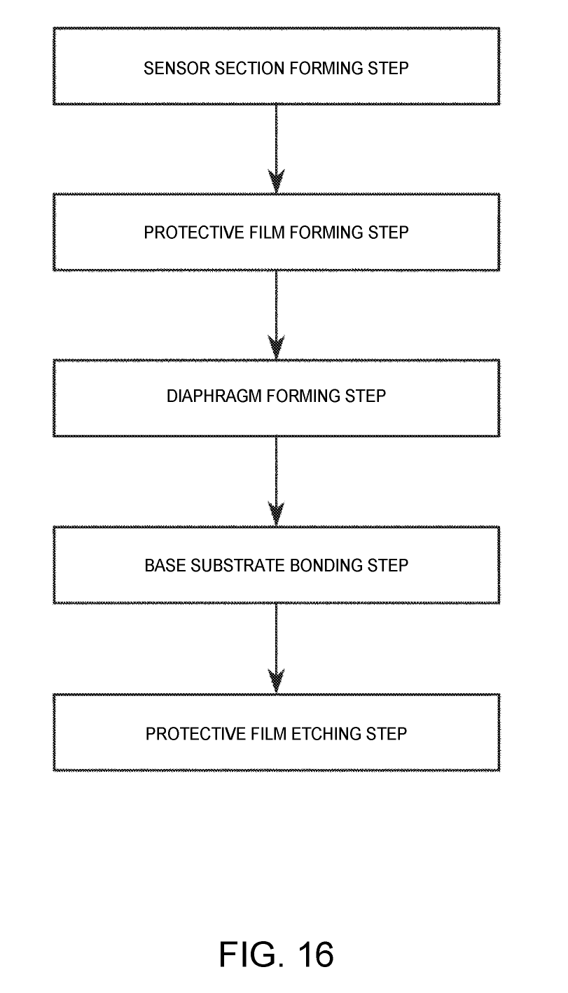

FIG. 1 is a cross-sectional view showing the pressure sensor according to the first embodiment of the invention. FIG. 2 is a plan view showing a sensor section included in the pressure sensor shown in FIG. 1. FIG. 3 is a circuit diagram showing a bridge circuit including the sensor section shown in FIG. 2. FIG. 4 is a plan view showing a protective film included in the pressure sensor shown in FIG. 1. FIG. 5 is a cross-sectional view showing a variation of the pressure sensor shown in FIG. 1. FIG. 6 is a flowchart showing a production step of the pressure sensor shown in FIG. 1. FIGS. 7 to 15 are each a cross-sectional view for illustrating a production method for the pressure sensor shown in FIG. 1. FIG. 16 is a flowchart showing another production step of the pressure sensor shown in FIG. 1. In the following description, the upper side in each of FIGS. 1, 5, and 7 to 15, and the front side of each of FIGS. 2 and 4 are also referred to as “upper” and the lower side in each of FIGS. 1, 5, and 7 to 15, and the rear side of each of FIGS. 2 and 4 are also referred to as “lower”.

As shown in FIG. 1, a pressure sensor 1 includes a substrate 2, a sensor section 3 which is placed on the substrate 2, a protective film 5 which is placed on the upper surface of the substrate 2, a base substrate 4 which is bonded to the lower surface of the substrate 2, and a pressure reference chamber S (cavity section) which is formed between the substrate 2 and the base substrate 4.

The substrate 2 is an SOI substrate in which a first silicon layer 21, a silicon oxide layer 22, and a second silicon layer 23 are stacked in this order. However, the substrate 2 is not limited to the SOI substrate, and for example, a single-layer silicon substrate may be used. As the substrate 2, a substrate (semiconductor substrate) constituted by a semiconductor material other than silicon, for example, germanium, gallium arsenide, gallium arsenide phosphide, gallium nitride, silicon carbide, or the like may be used.

Further, in the substrate 2, a diaphragm 25 which is thinner than the peripheral portion and is flexurally deformed by receiving a pressure is provided. In the substrate 2, a bottomed recessed section 24 which opens downward is formed, and a portion on the upper side of this recessed section 24 (a portion where the substrate 2 is thinned due to the recessed section 24) becomes the diaphragm 25. Then, the upper surface of the diaphragm 25 becomes a pressure receiving surface 251 which receives a pressure. The recessed section 24 is a space (cavity section) for forming the below-mentioned pressure reference chamber S formed on the opposite side to the pressure receiving surface of the diaphragm 25.

Here, in this embodiment, the recessed section 24 is formed by dry etching using a silicon deep etching device. Specifically, the recessed section 24 is formed by repeating the step of isotropic etching, protective film formation, and anisotropic etching from the lower surface side of the substrate 2 so as to dig the first silicon layer 21. When etching reaches the silicon oxide layer 22 by repeating this step, the silicon oxide layer 22 serves as an etching stopper and the etching is terminated, whereby the recessed section 24 is obtained. According to such a forming method, the side surface of the recessed section 24 is substantially perpendicular to the main surface of the substrate 2, and therefore, the opening area of the recessed section 24 can be made small. Therefore, a decrease in the mechanical strength of the substrate 2 can be suppressed, and also an increase in the size of the pressure sensor 1 can be suppressed. Although not shown in the drawing, by repeating the above-mentioned step, periodic irregularities are formed in the digging direction on the inner wall side surface of the recessed section 24.

However, the forming method for the recessed section 24 is not limited to the above-mentioned method, and the recessed section 24 may be formed by, for example, wet etching. Further, in this embodiment, the silicon oxide layer 22 remains in the diaphragm 25, however, this silicon oxide layer 22 may be further removed. That is, the diaphragm 25 may be constituted by a single layer of the second silicon layer 23. According to this, the diaphragm 25 can be made thinner, and thus, the diaphragm 25 which is more easily flexurally deformed is obtained. Further, as in this embodiment, in a case where the diaphragm 25 is constituted by a plurality of layers (the silicon oxide layer 22 and the second silicon layer 23), a thermal stress attributed to a difference in the thermal expansion coefficient between respective layers is generated, and the diaphragm 25 may be flexurally deformed undesirably, that is, attributed to a force other than a pressure to be detected. On the other hand, by constituting the diaphragm 25 by a single layer, a thermal stress as described above is not generated, and therefore, a pressure to be detected can be more accurately detected.

The thickness of the diaphragm 25 is not particularly limited and varies also depending on the size or the like of the diaphragm 25, however, for example, in a case where the width of the diaphragm 25 is 100 μm or more and 300 μm or less, the thickness thereof is preferably 1 μm or more and 10 μm or less, more preferably 1 μm or more and 3 μm or less. More specifically, the thickness of the second silicon layer 23 constituting an upper portion of the diaphragm 25 is preferably 1 μm or more and 9 μm or less, more preferably 1 μm or more and 3 μm or less. Further, the thickness of the silicon oxide layer 22 constituting a lower portion of the diaphragm 25 is preferably 0.1 μm or more and 1 μm or less, more preferably 0.1 μm or more and 0.5 μm or less. According to this, the diaphragm 25 which is sufficiently thin and is more easily flexurally deformed by receiving a pressure while sufficiently maintaining the mechanical strength is obtained.

As shown in FIG. 2, the plan view shape of the diaphragm 25 is an approximate square. That is, the outer edge of the diaphragm 25 has four sides 25a, 25b, 25c, and 25d, and four corner sections 25ab, 25bc, 25cd, and 25da. More specifically, the corner section 25ab is provided in a portion where the side 25a and the side 25b intersect each other, the corner section 25bc is provided in a portion where the side 25b and the side 25c intersect each other, the corner section 25cd is provided in a portion where the side 25c and the side 25d intersect each other, and the corner section 25da is provided in a portion where the side 25d and the side 25a intersect each other. Each of the corner sections 25ab, 25bc, 25cd, and 25da may be linearly chamfered (C plane) or roundly chamfered (R plane). In this case, the chamfered range is not particularly limited and can be set to, for example, about 20% or less of the length of each of the sides 25a, 25b, 25c, and 25d, or can be set to about 10% or less thereof.

However, the plan view shape of the diaphragm 25 is not particularly limited, and may be, for example, a shape having corner sections such as a triangle or a polygon having 5 or more corners, or a shape having no corner sections such as a circle, an ellipse, or an elongated circle.

As shown in FIG. 2, the diaphragm 25 is provided with the sensor section 3 which detects a pressure to act on the diaphragm 25. The sensor section 3 includes four piezoresistive elements 31, 32, 33, and 34 provided in the diaphragm 25. The piezoresistive elements 31, 32, 33, and 34 are electrically connected to one another through a wiring 35 and constitute abridge circuit 30 (Wheatstone bridge circuit) shown in FIG. 3. To the bridge circuit 30, a drive circuit (not shown) which supplies a drive voltage AVDC is connected. Then, the bridge circuit 30 outputs a detection signal (voltage) in accordance with the change in the resistance value of the piezoresistive element 31, 32, 33, or 34 based on the flexure of the diaphragm 25. Due to this, a pressure received by the diaphragm 25 can be detected based on the detection signal output from the bridge circuit 30.

In particular, the piezoresistive elements 31, 32, 33, and 34 are placed in an outer edge portion of the diaphragm 25. Specifically, as shown in FIG. 2, the piezoresistive element 31 is placed along the side 25b, the piezoresistive element 32 is placed along the side 25d, the piezoresistive element 33 is placed along the side 25a, and the piezoresistive element 34 is placed along the side 25c. When the diaphragm 25 is flexurally deformed by receiving a pressure, a large stress is applied particularly to the outer edge portion in the diaphragm 25, and therefore, as in this embodiment, by placing the piezoresistive elements 31, 32, 33, and 34 in the outer edge portion of the diaphragm 25, the above-mentioned detection signal can be increased, and thus, the pressure detection sensitivity is improved. The placement of the piezoresistive elements 31, 32, 33, and 34 is not particularly limited, and for example, the piezoresistive elements 31, 32, 33, and 34 may be placed across the outer edge of the diaphragm 25, or may be placed in a central portion of the diaphragm 25.

Each of the piezoresistive elements 31, 32, 33, and 34 is formed by, for example, doping (diffusing or injecting) an impurity such as phosphorus or boron into the second silicon layer 23 of the substrate 2. The wiring 35 is formed by, for example, doping (diffusing or injecting) an impurity such as phosphorus or boron into the second silicon layer 23 of the substrate 2 at a higher concentration than in the piezoresistive elements 31, 32, 33, and 34. However, the forming method for the piezoresistive elements 31, 32, 33, and 34 or the wiring 35 is not particularly limited.

As shown in FIG. 1, the protective film 5 is placed on the upper surface of the substrate 2. The protective film 5 includes a first insulating film 51 placed on the upper surface of the substrate 2 and a second insulating film 52 placed on the first insulating film 51. Further, the first insulating film 51 is constituted by a silicon oxide film (SiO₂ film) and a second insulating film 52 is constituted by a silicon nitride film (SiNx film).

Each of the first insulating film 51 and the second insulating film 52 is placed so as to overlap with the entire region of the diaphragm 25 in a plan view of the substrate 2. By the first insulating film 51 (silicon oxide film), the interface states of the piezoresistive elements 31, 32, 33, and 34 are reduced, and the occurrence of noise can be suppressed. Further, by the second insulating film 52 (silicon nitride film), the sensor section 3 can be protected from water and dust, and the reliability of the pressure sensor 1 can be enhanced.

Here, the sum of the thicknesses (total thickness) of the first insulating film 51 and the second insulating film 52 is not particularly limited, but is preferably 1/10 or less of the thickness of the diaphragm 25. According to this, with respect to the diaphragm 25, the first insulating film 51 and the second insulating film 52 can be made sufficiently thin. Therefore, it is possible to effectively prevent the diaphragm 25 from becoming difficult to be flexurally deformed due to the first insulating film 51 and the second insulating film 52.

Further, by making the first insulating film 51 and the second insulating film 52 thin, an effect as described below can also be exhibited. In this embodiment, it can also be said that a stacked body of the diaphragm 25, the first insulating film 51, and the second insulating film 52 functions as the “diaphragm” which is flexurally deformed by receiving a pressure. When discussing this diaphragm in terms of the thickness direction thereof, a stress generated when the diaphragm is flexurally deformed by receiving a pressure increases from a central portion to the surfaces (the upper surface and the lower surface) in the thickness direction of the diaphragm. Therefore, by placing the piezoresistive elements 31, 32, 33, and 34 closer to the upper surface or the lower surface of the diaphragm, even in a case where the same pressure is received, a larger detection signal is obtained. In light of this, as described above, by making the first insulating film 51 and the second insulating film 52 thin, the piezoresistive elements 31, 32, 33, and 34 can be placed closer to the upper surface of the diaphragm, and therefore, a larger detection signal is obtained, and the pressure detection sensitivity is further enhanced.

The thickness of the first insulating film 51 is not particularly limited, however, in a case where the thickness of the diaphragm 25 is 1 μm or more and 10 μm or less, the thickness of the first insulating film 51 is preferably, for example, 100 Å or more and 1000 Å or less, more preferably 300 Å or more and 500 Å or less, further more preferably 450 Å or more and 550 Å or less. According to this, the first insulating film 51 can be made sufficiently thin while sufficiently exhibiting the above-mentioned effect.

Further, the thickness of the second insulating film 52 is not particularly limited, however, in a case where the thickness of the diaphragm 25 is 1 μm or more and 10 μm or less, the thickness of the second insulating film 52 is preferably, for example, 100 Å or more and 2000 Å or less, more preferably 500 Å or more and 1500 Å or less, further more preferably 900 Å or more and 1100 Å or less. According to this, the second insulating film 52 can be made sufficiently thin while sufficiently exhibiting the above-mentioned effect.

In this embodiment, the first insulating film 51 is constituted by silicon oxide, but may contain a material other than silicon oxide (for example, a material inevitably mixed therein in the production). Similarly, in this embodiment, the second insulating film 52 is constituted by silicon nitride, but may contain a material other than silicon nitride (for example, a material inevitably mixed therein in the production). Further, in this embodiment, the first insulating film 51 and the second insulating film 52 are stacked on the substrate 2, however, for example, a silicon oxynitride film (SiNO film) may be placed instead of these. When using the silicon oxynitride film, the functions of both of the above-mentioned first insulating film 51 and second insulating film 52 can be exhibited, and moreover, only one layer is sufficient, and therefore, the protective film 5 on the diaphragm 25 can be made thinner.

As shown in FIG. 1, the protective film 5 includes a third insulating film 53, a fourth insulating film 54, and a surface protective film 55 in addition to the above-mentioned first insulating film 51 and second insulating film 52.

The third insulating film 53 is placed on the second insulating film 52. Further, on the third insulating film 53, a wiring 6 is provided. In the third insulating film 53, a through-hole is formed, and the wiring 6 and the wiring 35 are electrically connected through this through-hole. The third insulating film 53 functions as an interlayer insulating film which insulates the wiring 6 from the wiring 35. Further, on the third insulating film 53 and the wiring 6, the fourth insulating film 54 is placed. By this fourth insulating film 54, the wiring 6 is insulated and also protected. The third insulating film 53 and the fourth insulating film 54 are each constituted by, for example, a silicon oxide film. Further, the wiring 6 is constituted by, for example, a metal film such as an aluminum film. However, the constituent materials of these members are not particularly limited as long as they can exhibit their functions.

The thickness of each of the third insulating film 53 and the fourth insulating film 54 is not particularly limited, but is preferably, for example, 2000 Å or more and 8000 Å or less, more preferably 3000 Å or more and 5000 Å or less. According to this, while suppressing an excessive increase in the thickness of the protective film 5, each of the third insulating film 53 and the fourth insulating film 54 can be made to more reliably exhibit the intended function (insulation).

On the fourth insulating film 54, the surface protective film 55 is placed. The surface protective film 55 has a function of protecting the pressure sensor 1 from water and dust. Such a surface protective film 55 is constituted by, for example, a silicon nitride film. However, the constituent material of the surface protective film is not particularly limited as long as the function can be exhibited. Further, a through-hole penetrating the surface protective film 55 and the fourth insulating film 54 is provided, and on the surface protective film 55, a terminal 7 electrically connected to the wiring 6 through this through-hole is provided.

The thickness of the surface protective film 55 is not particularly limited, but is preferably, for example, 3000 Å or more and 9000 Å or less, more preferably 5000 Å or more and 7000 Å or less. According to this, while suppressing an excessive increase in the thickness of the protective film 5, the surface protective film 55 can be made to more reliably exhibit the intended function (protection from water and dust).

Hereinabove, the third insulating film 53, the fourth insulating film 54, and the surface protective film 55 have been described. As shown in FIGS. 1 and 4, the third insulating film 53, the fourth insulating film 54, and the surface protective film 55 each have a frame shape and are placed so as to surround the diaphragm 25 in a plan view of the substrate 2.

Therefore, it can be said that the protective film 5 has a shape with a recessed section 50 which opens to the upper surface of the protective film 5 and penetrates the third insulating film 53, the fourth insulating film 54, and the surface protective film 55. Further, because of such a shape, it can also be said that the protective film 5 has a thin section 58 which is a portion overlapping with the recessed section 50 and a thick section 59 which is located around the recessed section 50 and is thicker than the thin section 58. In this embodiment, the thin section 58 is constituted by the following two layers: the first insulating film 51 and the second insulating film 52, and the thick section 59 is constituted by the first insulating film 51, the second insulating film 52, the third insulating film 53, the fourth insulating film 54, and the surface protective film 55. However, the configuration of each of the thin section 58 and the thick section 59 is not particularly limited.

In this manner, by providing the thin section 58, it is possible to prevent the diaphragm 25 from becoming difficult to be flexed by the protective film 5 as described above. Further, by providing the thick section 59, it is possible to enhance the mechanical strength of the pressure sensor 1. That is, according to such a protective film 5, while suppressing the decrease in the pressure detection sensitivity of the pressure sensor 1, the mechanical strength can be enhanced.

As shown in FIG. 4, in the pressure sensor 1, the thin section 58 is placed so as to overlap with the piezoresistive elements 31, 32, 33, and 34 in a plan view of the substrate 2. In other words, the thick section 59 is located outside the piezoresistive elements 31, 32, 33, and 34 and is placed so as not to overlap with the piezoresistive elements 31, 32, 33, and 34. According to this, when receiving a pressure, a region of the diaphragm 25 where the piezoresistive elements 31, 32, 33, and 34 are placed can be more reliably flexurally deformed, and the decrease in the pressure detection sensitivity can be suppressed.

Further, the thick section 59 is placed so as to overlap with at least a part of the outer edge of the diaphragm 25 in a plan view of the substrate 2. According to this, the outer edge portion of the diaphragm 25 can be reinforced by the thick section 59. As described above, a larger stress is more likely to be applied to the outer edge portion of the diaphragm 25 than the other portions when it receives a pressure, and therefore the outer edge portion is more likely to be damaged than the other portions. Therefore, as in this embodiment, by placing the thick section 59 so as to overlap with at least a part of the outer edge of the diaphragm 25, the mechanical strength of the outer edge of the diaphragm 25 is enhanced, and thus, the breakage of the diaphragm 25 can be effectively suppressed. Due to this, the pressure resistance strength of the pressure sensor 1 is improved. Further, the breakage of the diaphragm 25 during the production step of the pressure sensor 1 can be suppressed, and the yield is improved.

As described above, the diaphragm 25 has an approximate square shape in a plan view of the substrate 2, and the outer edge thereof has the four sides 25a, 25b, 25c, and 25d, and the four corner sections 25ab, 25bc, 25cd, and 25da. In this manner, when the outer edge of the diaphragm 25 has a corner section, a stress is likely to be concentrated particularly on the corner section in the outer edge, and the diaphragm 25 is often broken from the corner section. Therefore, the thick section 59 is placed so as to overlap with the corner sections 25ab, 25bc, 25cd, and 25da. Accordingly, the corner sections 25ab, 25bc, 25cd, and 25da can be reinforced by the thick section 59. Due to this, the breakage of the diaphragm 25 triggered by stress concentration on the corner sections 25ab, 25bc, 25cd, and 25da as described above can be effectively suppressed.

In this embodiment, the thick section 59 is provided so as to overlap with all the corner sections 25ab, 25bc, 25cd, and 25da, however, the configuration is not limited thereto and may be any as long as the thick section 59 is provided so as to overlap with at least one of the corner sections 25ab, 25bc, 25cd, and 25da.

On the other hand, the thick section 59 is located outside the four sides 25a, 25b, 25c, and 25d so as not to overlap with the sides 25a, 25b, 25c, and 25d. In other words, the thin section 58 is placed so as to overlap with the four sides 25a, 25b, 25c, and 25d. As described above, the piezoresistive element 33 is placed along the side 25a, the piezoresistive element 31 is placed along the side 25b, the piezoresistive element 34 is placed along the side 25c, and the piezoresistive element 32 is placed along the side 25d. Therefore, by locating the thick section 59 outside the respective sides 25a, 25b, 25c, and 25d, the decrease in the pressure detection sensitivity due to the overlapping of the thick section 59 with the piezoresistive elements 31, 32, 33, and 34 can be effectively suppressed.

A distance d1 between each of the sides 25a, 25b, 25c, and 25d and the inner peripheral surface of the thick section 59 is not particularly limited and varies depending on the amount of positional shift (alignment accuracy) of the thick section 59 with respect to the diaphragm 25 which can occur during production, but is preferably, for example, 6 μm or more and 20 μm or less. According to this, a positional shift due to a production error can be sufficiently permitted, and even if the position of the thick section 59 with respect to the diaphragm 25 is shifted, the thick section 59 can be more reliably prevented from overlapping with the piezoresistive elements 31, 32, 33, and 34. Further, the thick section 59 can be prevented from being separated from the diaphragm 25, and thus, the decrease in the mechanical strength of the pressure sensor 1 can be more effectively suppressed.

In this embodiment, the thick section 59 is located outside the sides 25a, 25b, 25c, and 25d, however, the configuration is not limited thereto as long as the thick section 59 does not overlap with the piezoresistive elements 31, 32, 33, and 34. For example, the inner periphery of the thick section 59 may overlap with the sides 25a, 25b, 25c, and 25d, or may be located inside the sides 25a, 25b, 25c, and 25d.

The inner periphery of the thick section 59 (that is, the plan view shape of the thin section 58) has an approximately square shape and has four sides 59a, 59b, 59c, and 59d and four corner sections 59ab, 59bc, 59cd, and 59da. Then, the sides 59a, 59b, 59c, and 59d of the inner periphery of the thick section 59 are provided along the sides 25a, 25b, 25c, and 25d of the diaphragm 25, and the corner sections 59ab, 59bc, 59cd, and 59da of the inner periphery of the thick section 59 are provided corresponding to the corner sections 25ab, 25bc, 25cd, and 25da of the diaphragm 25. In this manner, by making the inner periphery of the thick section 59 correspond to the shape of the diaphragm 25, the inner periphery of the thick section 59 can be placed closer to the diaphragm 25. Therefore, the thick section 59 can be placed more widely, and the mechanical strength of the pressure sensor 1 can be further enhanced.

The width W59 of the inner periphery of the thick section 59 is larger than the width W25 of the diaphragm 25. According to this, the sides 59a, 59b, 59c, and 59d can be more reliably located outside the sides 25a, 25b, 25c, and 25d. Further, each of the corner sections 59ab, 59bc, 59cd, and 59da is chamfered. In this manner, by chamfering each of the corner sections 59ab, 59bc, 59cd, and 59da, while satisfying the following relationship: W59>W25, the length L59 in the diagonal direction of the inner periphery of the thick section 59 can be made shorter than the length L25 in the diagonal direction of the diaphragm 25. Therefore, each of the corner sections 59ab, 59bc, 59cd, and 59da can be located inside the corner sections 25ab, 25bc, 25cd, and 25da, and the thick section 59 can be placed so as to overlap with the corner sections 25ab, 25bc, 25cd, and 25da.

Here, a distance d2 between each of the corner sections 25ab, 25bc, 25cd, and 25da of the diaphragm 25 and each of the corner sections 59ab, 59bc, 59cd, and 59da of the thick section 59 is not particularly limited, but is preferably, for example, 5 μm or more and 20 μm or less, more preferably 5 μm or more and 15 μm or less. According to this, while suppressing the excessive overlapping of the thick section 59 with the diaphragm 25 so as to suppress the reduction in the space where the piezoresistive elements 31, 32, 33, and 34 are placed, the corner sections 25ab, 25bc, 25cd, and 25da can be sufficiently reinforced by the thick section 59.

In particular, in this embodiment, each of the corner sections 59ab, 59bc, 59cd, and 59da is arcuately curved so as to project outward. According to this, stress concentration on each of the corner sections 59ab, 59bc, 59cd, and 59da can be more effectively suppressed, and the breakage or the like of the protective film 5 triggered by stress concentration on each of the corner sections 59ab, 59bc, 59cd, and 59da can be effectively suppressed. However, the shape of each of the corner sections 59ab, 59bc, 59cd, and 59da is not particularly limited, and may be, for example, a linear shape, or may be curved so as to project inward.

As shown in FIG. 1, the base substrate 4 is placed facing the diaphragm 25 so as to form the pressure reference chamber S between the base substrate 4 and the diaphragm 25. Further, the base substrate 4 is bonded to the lower surface of the substrate 2 so as to close the opening of the recessed section 24. As the base substrate 4, for example, a silicon substrate, a glass substrate, a ceramic substrate, or the like can be used.

By airtightly sealing the recessed section 24 with the base substrate 4, the pressure reference chamber S is formed. Therefore, it can be said that the pressure reference chamber S is located on the lower side of the diaphragm 25 (on the opposite side to the pressure receiving surface 251), and is placed so as to overlap with the diaphragm 25 in a plan view of the substrate 2. In this manner, by providing the pressure reference chamber S, a pressure received by the diaphragm 25 can be detected on the basis of the pressure in the pressure reference chamber S, and therefore, the pressure received by the diaphragm 25 can be more accurately detected.

The pressure reference chamber S is preferably in a vacuum state (for example, about 10 Pa or less). According to this, the pressure sensor 1 can be used as an “absolute pressure sensor” which detects a pressure with reference to vacuum. Therefore, the pressure sensor 1 with high convenience is formed. However, the pressure reference chamber S may not be in a vacuum state. The invention can also be applied to a differential pressure sensor or a gauge pressure sensor in which a pressure inlet is formed in the base substrate 4 so that the recessed section 24 is made to communicate with the outside.

Hereinabove, the pressure sensor 1 has been described. As described above, such a pressure sensor 1 includes the substrate 2 which includes the diaphragm 25 that is flexurally deformed by receiving a pressure, the piezoresistive elements 31, 32, 33, and 34 which are provided in the diaphragm 25, and the protective film 5 which is provided on the upper surface (one surface) side of the diaphragm 25. Further, the protective film 5 includes the thin section 58 and the thick section 59 which is thicker than the thin section 58. Further, in a plan view of the substrate 2, the thin section 59 overlaps with the piezoresistive elements 31, 32, 33, and 34, and the thick section 59 overlaps with at least a part of the diaphragm 25. According to this, a region of the diaphragm 25 where the piezoresistive elements 31, 32, 33, and 34 are placed can be more reliably flexurally deformed, and the decrease in the pressure detection sensitivity can be suppressed. Moreover, by the thick section 59, the mechanical strength of the diaphragm 25 is enhanced, and thus, the breakage of the diaphragm 25 can be effectively suppressed. According to this, the pressure sensor 1 which can achieve both pressure detection sensitivity and mechanical strength is formed.

Further, as described above, in the pressure sensor 1, the thick section 59 overlaps with at least a part of the outer edge of the diaphragm 25 in a plan view of the substrate 2. According to this, the mechanical strength of the outer edge of the diaphragm 25 can be enhanced by the thick section 59, and therefore, the breakage of the diaphragm 25 triggered by stress concentration on the outer edge can be effectively suppressed. Accordingly, both pressure detection sensitivity and mechanical strength can be more effectively achieved.

Further, as described above, in the pressure sensor 1, the outer edge of the diaphragm 25 has at least one corner section, and the thick section 59 overlaps with the corner section in a plan view of the substrate 2. In particular, in this embodiment, the diaphragm 25 has the four corner sections 25ab, 25bc, 25cd, and 25da, and the thick section 59 overlaps with all the corner sections 25ab, 25bc, 25cd, and 25da. In a case where the outer edge of the diaphragm 25 has a corner section in this manner, a stress is likely to be concentrated particularly on the corner section in the outer edge, and the diaphragm 25 is often broken from the corner section. Therefore, by placing the thick section 59 so as to overlap with the respective corner sections 25ab, 25bc, 25cd, and 25da and reinforcing the corner sections 25ab, 25bc, 25cd, and 25da, the breakage of the diaphragm 25 triggered by stress concentration on the corner sections 25ab, 25bc, 25cd, and 25da can be effectively suppressed.

Further, as described above, in the pressure sensor 1, in a plan view of the substrate 2, the outer edge of the diaphragm 25 has at least two corner sections and a side located between the two corner sections. The thick section 59 overlaps with the respective corner sections, and the thin section 58 overlaps with the side. In particular, in this embodiment, the outer edge of the diaphragm 25 has the four corner sections 25ab, 25bc, 25cd, and 25da, and the sides 25a, 25b, 25c, and 25d, each of which is located between these corner sections 25ab, 25bc, 25cd, and 25da. Then, the thick section 59 overlaps with the respective corner sections 25ab, 25bc, 25cd, and 25da, and the thin section 58 overlaps with the respective sides 25a, 25b, 25c, and 25d. According to this, the piezoresistive elements 31, 32, 33, and 34 are easily placed in the outer edge portion of the diaphragm 25. Further, the decrease in the pressure detection sensitivity due to the overlapping of the thick section 59 with the piezoresistive elements 31, 32, 33, and 34 can be effectively suppressed.

Further, as described above, in the pressure sensor 1, the piezoresistive elements 31, 32, 33, and 34 are placed in the outer edge portion of the diaphragm 25. When the diaphragm 25 is flexurally deformed by receiving a pressure, a large stress is applied particularly to the outer edge portion in the diaphragm 25, and therefore, by placing the piezoresistive elements in the outer edge portion, the detection signal can be increased. Therefore, the pressure detection sensitivity of the pressure sensor 1 is improved.

Further, as described above, in the pressure sensor 1, the thin section 58 includes a first insulating film 51 containing silicon oxide and a second insulating film 52 containing silicon nitride. Therefore, by the first insulating film 51, the interface states of the piezoresistive elements 31, 32, 33, and 34 are reduced, and the occurrence of noise can be suppressed. Further, by the second insulating film 52, the sensor section 3 can be protected from water and dust, and the reliability of the pressure sensor 1 can be enhanced.

Further, as described above, the pressure sensor 1 includes the pressure reference chamber S placed so as to overlap with the diaphragm 25 in a plan view of the substrate 2. In this manner, by providing the pressure reference chamber S, a pressure received by the diaphragm 25 can be detected on the basis of the pressure in the pressure reference chamber S, and therefore, the pressure received by the diaphragm 25 can be more accurately detected.

Hereinabove, the pressure sensor 1 has been described, however, the configuration of the pressure sensor 1 is not particularly limited. For example, in this embodiment, the recessed section 50 of the protective film 5 is formed penetrating the third insulating film 53, and the thin section 58 is constituted by a stacked body of the first insulating film 51 and the second insulating film 52, however, for example, as shown in FIG. 5, the recessed section 50 may be formed penetrating the surface protective film 55, and the thin section 58 may be constituted by a stacked body of the first insulating film 51, the second insulating film 52, the third insulating film 53, and the fourth insulating film 54. In addition thereto, a configuration in which the recessed section 50 is formed to the middle of the surface protective film 55, a configuration in which the recessed section 50 is formed to the middle of the third insulating film 53 and the fourth insulating film 54, a configuration in which the recessed section 50 is formed to the middle of the second insulating film 52, and the like may be adopted.

Next, a production method for the pressure sensor 1 will be described. As shown in FIG. 6, the production method for the pressure sensor 1 includes a sensor section forming step, a protective film forming step, a protective film etching step, a diaphragm forming step, and a base substrate bonding step.

### Sensor Section Forming Step

First, as shown in FIG. 7, the substrate 2 composed of an SOI substrate in which the first silicon layer 21, the silicon oxide layer 22, and the second silicon layer 23 are stacked is prepared, and the first insulating film 51 (silicon oxide film) is formed on the upper surface of the substrate 2 by, for example, thermally oxidizing the surface of the second silicon layer 23. Subsequently, as shown in FIG. 8, the sensor section 3 is formed on the upper surface of the substrate 2. The sensor section 3 can be formed by doping (diffusing or injecting) an impurity such as phosphorus or boron into the upper surface (second silicon layer 23) of the substrate 2.

### Protective Film Forming Step

Subsequently, as shown in FIG. 9, the second insulating film 52 (silicon nitride film) is formed on the first insulating film 51. This second insulating film 52 can be formed by, for example, thermal nitridation or reduced pressure CVD (LP-CVD). In particular, in a case where the second insulating film is formed by reduced pressure CVD (LP-CVD), the second insulating film 52 which has a low hydrogen content and also has favorable and uniform film quality can be formed. The reduced pressure CVD is performed, for example, in an environment at 700° C. or higher, however, at this time point, the wiring 6 constituted by a metal material such as aluminum is not formed. Therefore, the wiring 6 is not damaged (for example, disconnection due to softening or melting) by the reduced pressure CVD.

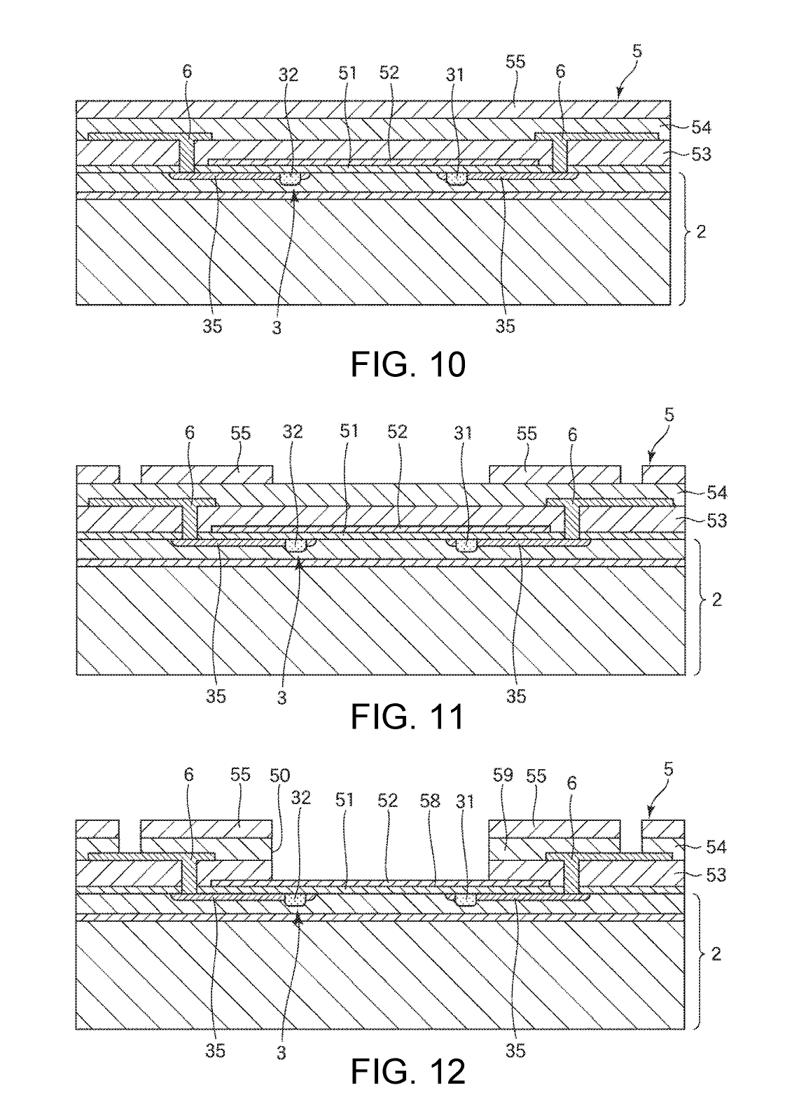

Subsequently, the second insulating film 52 is patterned using a photolithographic technique and an etching technique, and thereafter, as shown in FIG. 10, on the substrate 2, the third insulating film 53, the wiring 6, the fourth insulating film 54, and the surface protective film 55 are sequentially formed using a sputtering method, a CVD method, or the like. By doing this, the protective film 5 is obtained.

The third insulating film 53 and the fourth insulating film 54 are each constituted by, for example, a silicon oxide film, the wiring 6 is constituted by, for example, a metal film such as an aluminum film, and the surface protective film 55 is constituted by, for example, a silicon nitride film. The wiring 6 is patterned in a predetermined form using, for example, a photolithographic technique and an etching technique.

### Protective Film Etching Step

Subsequently, in order to form the thin section 58 and the terminal 7, as shown in FIG. 11, a part of the surface protective film 55 is removed by wet etching. By using wet etching, the etching selection ratio between the surface protective film 55 and the fourth insulating film 54 can be relatively easily increased. Therefore, the fourth insulating film 54 can be used as an etching stopper, and in this step, the surface protective film 55 can be more reliably removed. However, the surface protective film 55 may be removed by dry etching.

Subsequently, as shown in FIG. 12, the third insulating film 53 and the fourth insulating film 54 are removed by wet etching through the portion where the surface protective film 55 is removed. By doing this, the recessed section 50 is formed, and the protective film 5 including the thin section and the thick section 59 is obtained. Further, simultaneously with this, a through-hole for forming the terminal 7 is obtained. By using wet etching, the etching selection ratio between the third and fourth insulating films 53 and 54 and the second insulating film 52 can be relatively easily increased. Therefore, the removal of the second insulating film 52 along with the third and fourth insulating films 53 and 54 in this step can be effectively suppressed.

Subsequently, on the surface protective film 55, the terminal 7 is formed using a sputtering method, a CVD method, or the like.

### Diaphragm Forming Step

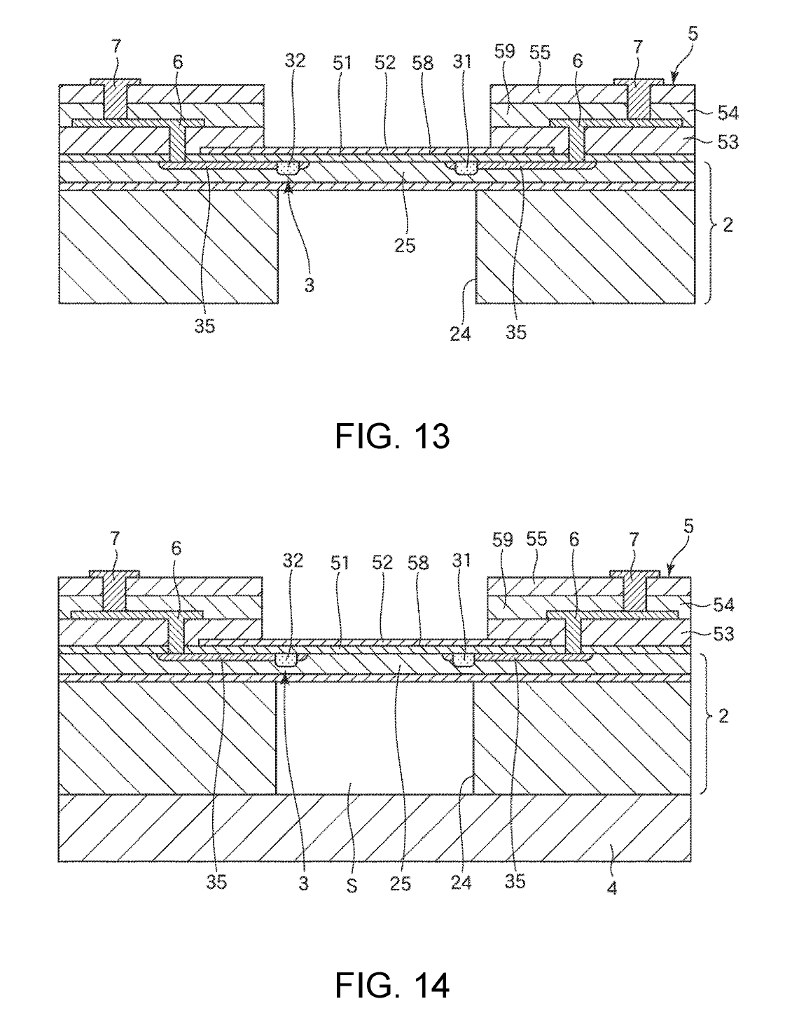

Subsequently, as shown in FIG. 13, the recessed section 24 which opens to the lower surface of the substrate 2 is formed, whereby the diaphragm 25 is obtained. The forming method for the recessed section 24 is not particularly limited, however, as described above, the recessed section 24 can be formed by dry etching using a silicon deep etching device.

### Base Substrate Bonding Step

Subsequently, as shown in FIG. 14, while bringing the inside of the recessed section 24 into a vacuum state, the base substrate 4 is bonded to the lower surface of the substrate 2 so as to close the opening of the recessed section 24. By doing this, the pressure reference chamber S in a vacuum state is obtained. The method for bonding the substrate 2 to the base substrate 4 is not particularly limited, and for example, a direct bonding method such as a surface activated bonding method can be used.

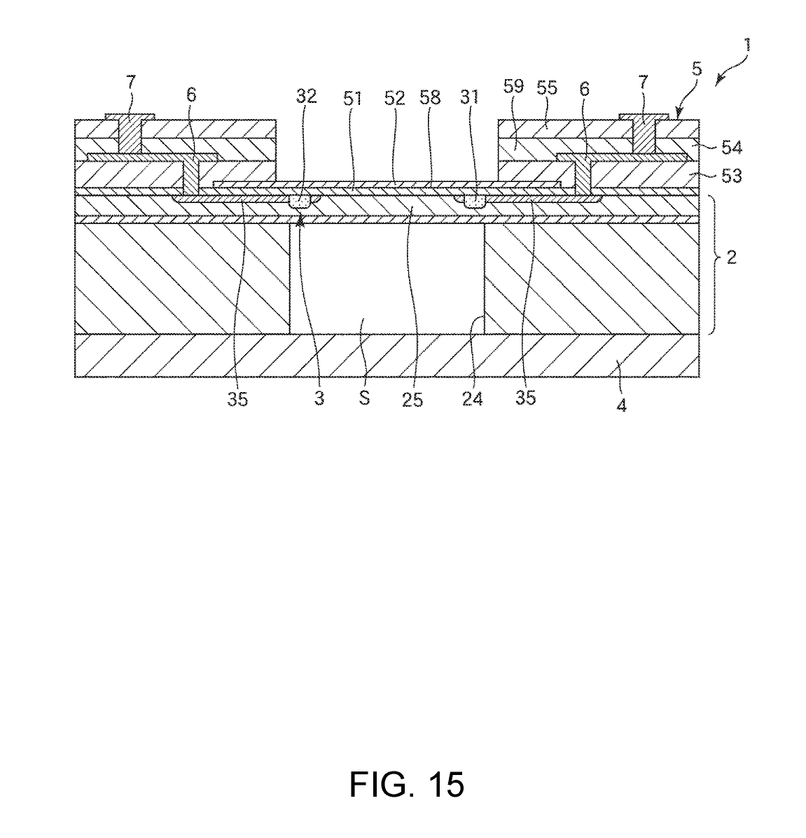

Subsequently, according to need, as shown in FIG. 15, the thickness of the base substrate 4 is adjusted to a predetermined value by polishing the base substrate 4 from the lower surface side by CMP (chemical mechanical polishing) or the like. In this manner, the pressure sensor 1 is obtained.

According to such a production method, production can be performed by a CMOS process all the way until the protective film etching step, and therefore, it is easy to control foreign substances or contamination, and thus, it becomes possible to produce the pressure sensor 1 while ensuring high yield and high productivity.

However, the production method for the pressure sensor 1 is not particularly limited, and for example, the protective film etching step may be performed after the base substrate bonding step. That is, as shown in FIG. 16, the sensor section forming step, the protective film forming step, the diaphragm forming step, the base substrate bonding step, and the protective film etching step may be performed in this order. According to this, the polishing of the base substrate 4 shown in FIG. 15 can be performed in a state where the entire region of the protective film 5 is thick. Due to this, the piezoresistive elements 31, 32, 33, and 34 can be more reliably protected during this step, and also the breakage of the diaphragm 25 during this step can be more effectively suppressed.

Further, for example, the diaphragm forming step may be performed prior to the sensor section forming step, the protective film forming step, or the protective film etching step.

### Second Embodiment

Next, a pressure sensor according to a second embodiment of the invention will be described.

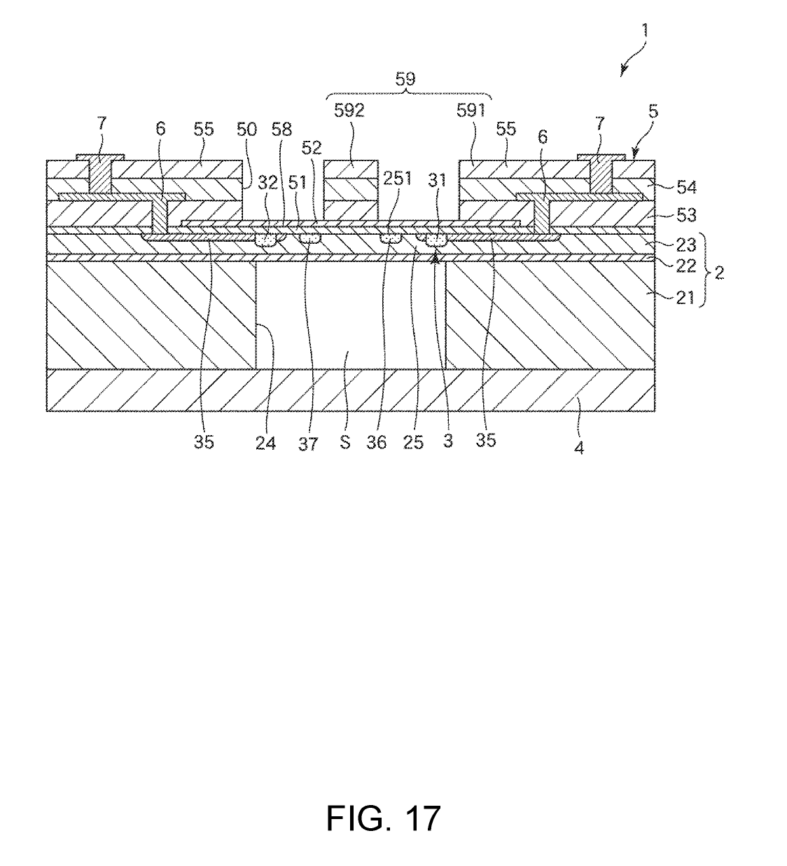

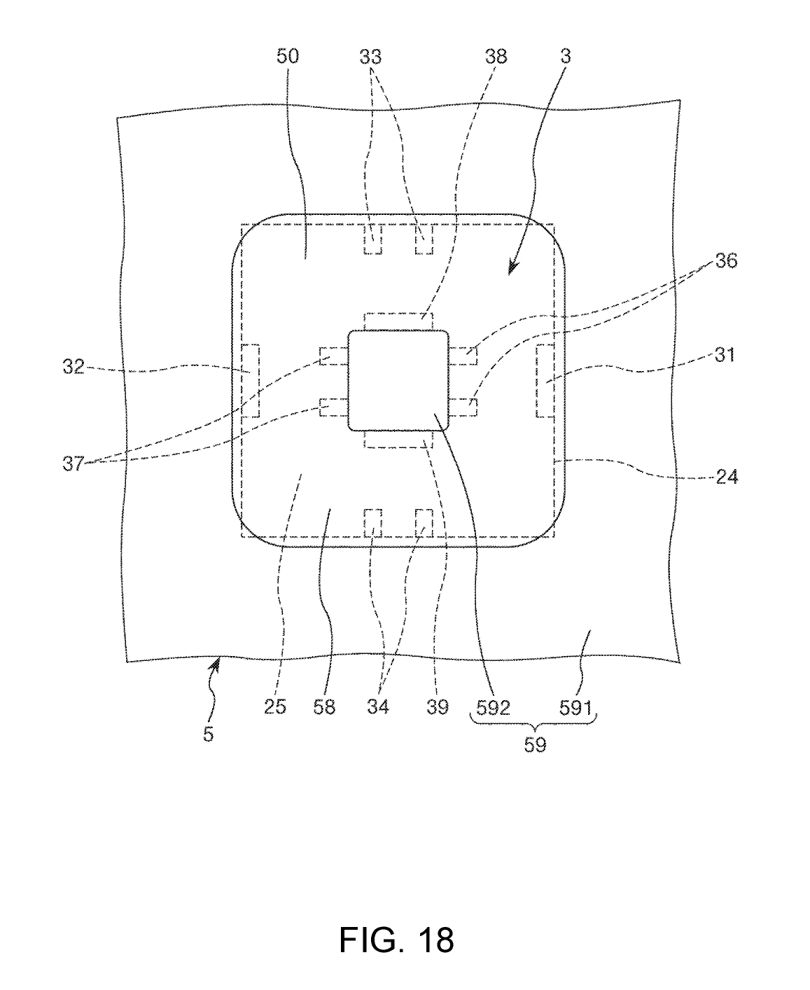

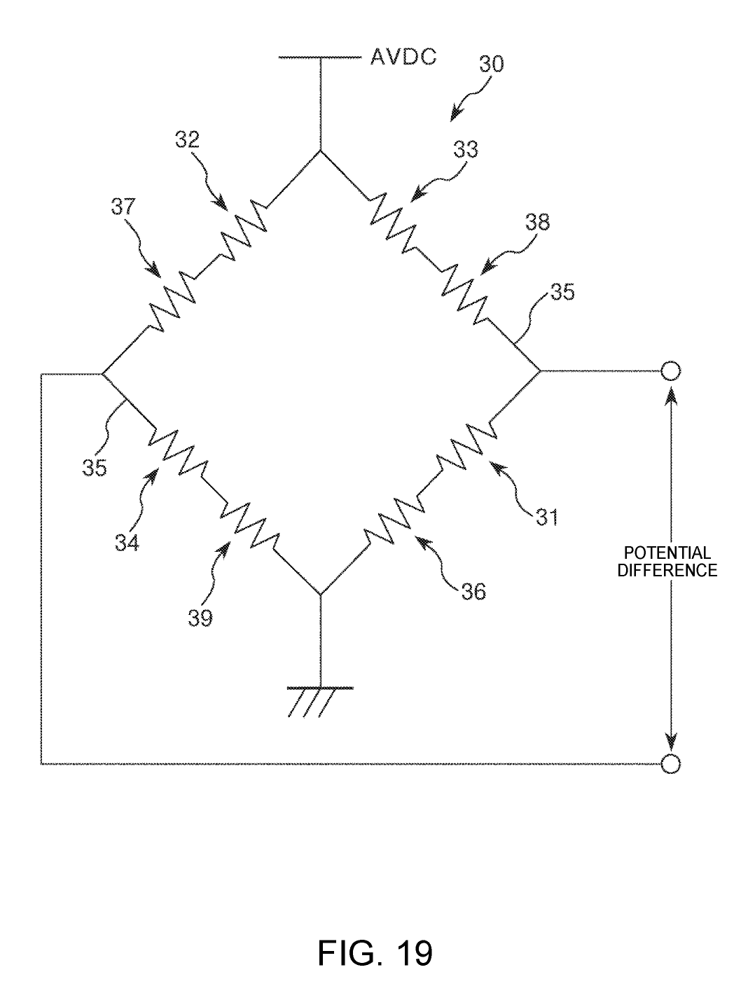

FIG. 17 is a cross-sectional view showing the pressure sensor according to the second embodiment of the invention. FIG. 18 is a plan view showing a protective film included in the pressure sensor shown in FIG. 17. FIG. 19 is a circuit diagram showing a bridge circuit including the sensor section shown in FIG. 18.

Hereinafter, with respect to the pressure sensor according to the second embodiment, different points from the above-mentioned embodiment will be mainly described, and the description of the same matter will be omitted.

The pressure sensor according to the second embodiment of the invention is substantially the same as that of the first embodiment described above except that the configuration of the protective film 5, and the number and the placement of piezoresistive elements are different. In FIGS. 17 to 19, the same components as those of the above-mentioned embodiment are denoted by the same reference numerals.

As shown in FIGS. 17 and 18, in the pressure sensor 1 according to this embodiment, the recessed section 50 of the protective film 5 has a frame shape (an annular shape) along the outer peripheral portion of the diaphragm 25 in a plan view of the substrate 2. Therefore, the thick section 59 includes a first thick section 591 located outside the recessed section 50 and a second thick section 592 located inside the recessed section 50. The first thick section 591 has the same configuration as the thick section 59 of the first embodiment described above, and therefore, the description thereof will be omitted.

The second thick section 592 is placed so as to overlap with a central portion of the diaphragm 25. Therefore, the rigidity of the central portion of the diaphragm 25 can be locally enhanced by the second thick section 592. Due to this, for example, as compared with the configuration in which the second thick section 592 is not provided (for example, the above-mentioned first embodiment), the stress value in the outer edge portion of the diaphragm 25 is improved. Further, not only in the outer edge portion of the diaphragm 25, but also in a boundary portion between a region which overlaps with the second thick section 592 and a region which does not overlap with the second thick section 592, a larger stress can be locally generated than in the other portions.

The outer shape of the second thick section 592 in a plan view of the substrate 2 is similar to the outer shape of the diaphragm 25 in a plan view of the substrate 2. However, the outer shape of the second thick section 592 is not particularly limited. Further, in this embodiment, the second thick section 592 has the same stacked structure as that of the first thick section 591, however, the configuration is not limited thereto, and the second thick section 592 may have a different stacked structure from that of the first thick section 591.

As described above, a large stress can be generated not only in the outer edge portion of the diaphragm 25, but also around the second thick section 592. Therefore, as shown in FIG. 18, the sensor section 3 includes piezoresistive elements 36, 37, 38, and 39 located around the second thick section 592 in addition to the piezoresistive elements 31, 32, 33, and 34 located in the outer edge portion of the diaphragm 25. The piezoresistive elements 31, 32, 33, 34, 36, 37, 38, and 39 constitute a bridge circuit 30 (Wheatstone bridge circuit) as shown in FIG. 19. According to this configuration, for example, as compared with the above-mentioned first embodiment, the number of piezoresistive elements included in the sensor section 3 is larger, and therefore, the detection sensitivity can be improved. The piezoresistive elements 36, 37, 38, and 39 may partially overlap with the second thick section 592.

The stress generated around the second thick section 592 of the diaphragm 25 is directed in the opposite direction to the stress generated in the outer edge portion, and therefore, the piezoresistive elements 36, 37, 38, and 39 extend in a direction orthogonal to the direction in which the corresponding piezoresistive elements 31, 32, 33, and 34 extend.

Hereinabove, the pressure sensor 1 according to this embodiment has been described. In such a pressure sensor 1, as described above, the thick section 59 includes a portion (second thick section 592) which overlaps with the central portion of the diaphragm 25. According to this, not only in the outer edge portion of the diaphragm 25, but also around the second thick section 592, a larger stress can be locally generated than in the other portions. Therefore, as in this embodiment, by also placing the piezoresistive elements 36, 37, 38, and 39 around the second thick section 592, the pressure detection sensitivity can be improved.

Further, as described above, in the pressure sensor 1 according to this embodiment, the piezoresistive elements (piezoresistive elements 36, 37, 38, and 39) are further placed in the central portion of the diaphragm 25. According to this, the number of piezoresistive elements is increased, and therefore, the detection sensitivity can be improved.

According also to the second embodiment, the same effect as that of the above-mentioned first embodiment can be exhibited.

In this embodiment, in the same manner as the above-mentioned first embodiment, in a plan view of the substrate 2, the first thick section 591 is placed so as to overlap with at least apart (corner portion) of the outer edge of the diaphragm 25, however, the configuration is not limited thereto, and the first thick section 591 may overlap with the outer edge of the diaphragm 25. That is, in a plan view of the substrate 2, the entire inner peripheral region of the first thick section 591 may be located outside the diaphragm 25.

### Third Embodiment

Next, a pressure sensor module according to a third embodiment of the invention will be described.

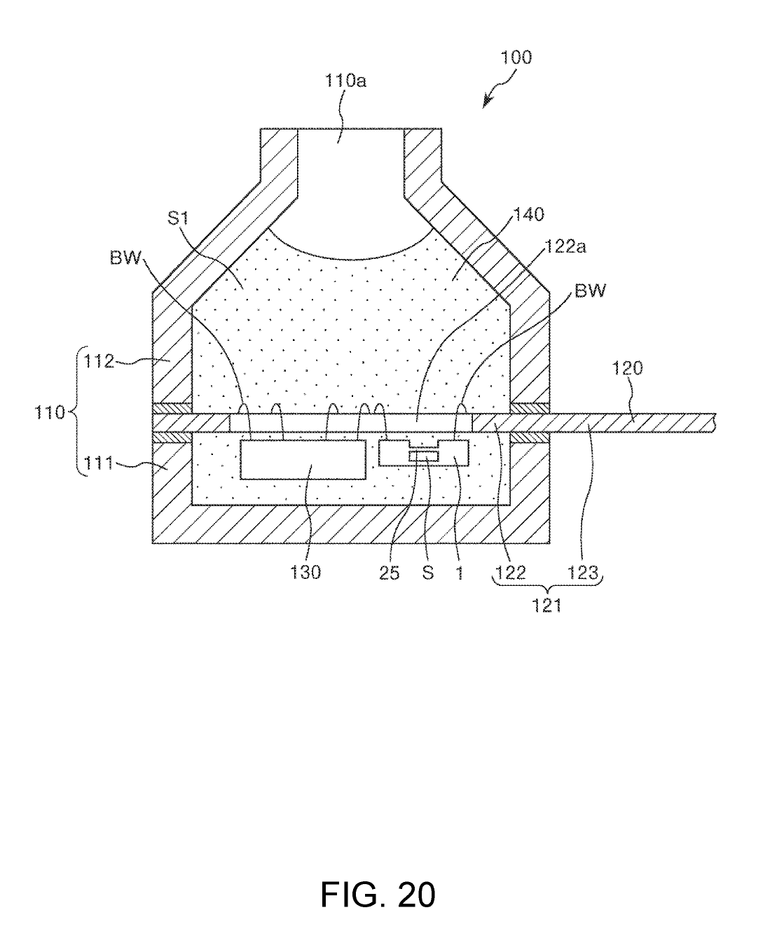

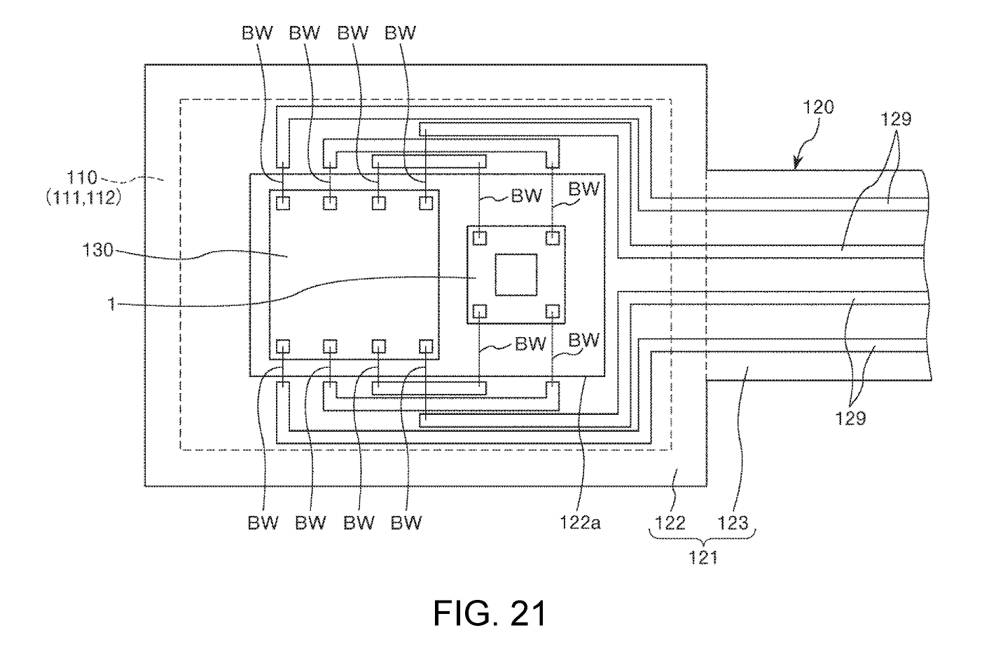

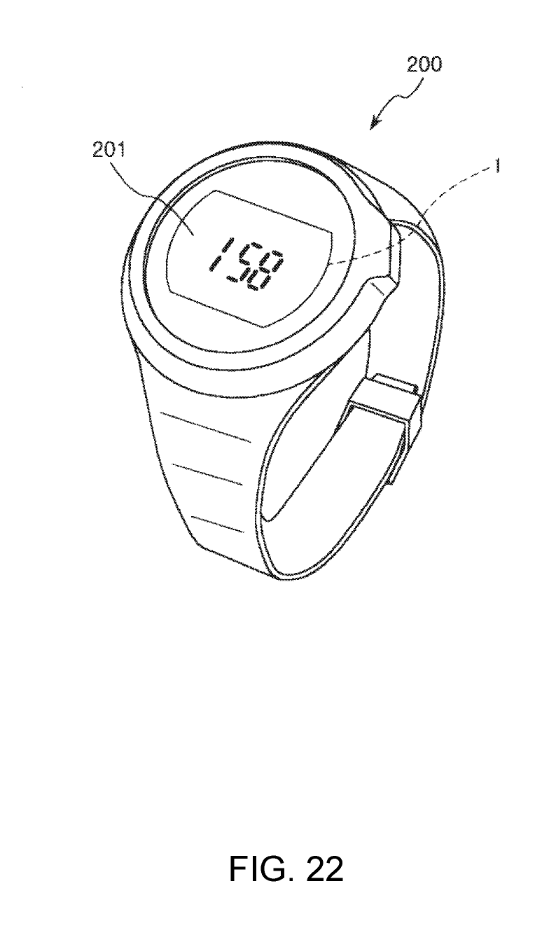

FIG. 20 is a cross-sectional view showing the pressure sensor module according to the third embodiment of the invention. FIG. 21 is a plan view of a support substrate included in the pressure sensor module shown in FIG. 20.

Hereinafter, with respect to the pressure sensor module according to the third embodiment, different points from the above-mentioned embodiment will be mainly described, and the description of the same matter will be omitted.

As shown in FIG. 20, a pressure sensor module 100 includes a package 110 which has an internal space S1, a support substrate 120 which is placed so as to be drawn out from the inside of the internal space S1 to the outside of the package 110, a circuit element 130 and a pressure sensor 1, each of which is supported by the support substrate 120 in the internal space S1, and a filling section 140 which is formed by filling a filler as described later in the internal space S1. According to such a pressure sensor module 100, the pressure sensor 1 can be protected by the package 110 and the filling section 140. As the pressure sensor 1, for example, the pressure sensor according to the embodiment described above can be used.

The package 110 includes a base 111 and a housing 112, and the base 111 and the housing 112 are bonded to each other through an adhesive layer so as to sandwich the support substrate 120 therebetween. The package 110 formed in this manner includes an opening 110a formed in the upper end portion thereof and the internal space S1 communicating with the opening 110a.

The constituent material of the base 111 and the housing 112 is not particularly limited, and examples thereof include insulating materials such as various types of ceramics including oxide ceramics such as alumina, silica, titania, and zirconia, and nitride ceramics such as silicon nitride, aluminum nitride, and titanium nitride, and various types of resin materials including polyethylene, polyamide, polyimide, polycarbonate, acrylic resins, ABS resins, and epoxy resins, and among these, it is possible to use one type or two or more types in combination. Above all, it is particularly preferred to use various types of ceramics.

Hereinabove, the package 110 has been described, however, the configuration of the package 110 is not particularly limited as long as the function can be exhibited.

The support substrate 120 is sandwiched between the base 111 and the housing 112 and placed so as to be drawn out from the inside of the internal space S1 to the outside of the package 110. Further, the support substrate 120 supports the circuit element 130 and the pressure sensor 1, and also electrically connects the circuit element 130 and the pressure sensor 1. Such a support substrate 120 includes a base material 121 having flexibility and a plurality of wirings 129 placed on the base material 121 as shown in FIG. 21.

The base material 121 includes a frame-shaped base section 122 having an opening 122a and a strip-shaped belt body 123 extending from the base section 122. The belt body 123 is sandwiched between the base 111 and the housing 112 in the outer edge portion of the base section 122 and extends to the outside of the package 110. As such a base material 121, for example, a generally used flexible printed circuit board can be used. In this embodiment, the base material 121 has flexibility, however, the entire or a part of the base material 121 may be a hard material.

The circuit element 130 and the pressure sensor 1 are located inside the opening 122a and are placed side by side in a plan view of the base material 121. Further, each of the circuit element 130 and the pressure sensor 1 is hung on the base material 121 through a bonding wire BW and is supported by the support substrate 120 in a floating state from the support substrate 120. Further, the circuit element 130 and the pressure sensor 1 are electrically connected through the bonding wires BW and the wirings 129. In this manner, by supporting the circuit element 130 and the pressure sensor 1 in a floating state with respect to the support substrate 120, a stress is less likely to be transmitted to the circuit element 130 and the pressure sensor 1 from the support substrate 120, and therefore, the pressure detection accuracy of the pressure sensor 1 is improved.

The circuit element 130 includes a drive circuit for supplying a voltage to the bridge circuit 30, a temperature compensation circuit for performing temperature compensation of an output from the bridge circuit 30, a pressure detection circuit which determines a pressure received from an output from the temperature compensation circuit, an output circuit which converts an output from the pressure detection circuit into a predetermined output form (CMOS, LV-PECL, LVDS, or the like) and outputs the converted output, and the like.

The filling section 140 is placed in the internal space S1 so as to cover the circuit element 130 and the pressure sensor 1. By such a filling section 140, the circuit element 130 and the pressure sensor 1 are protected (protected from dust and water), and also an external stress (for example, a drop impact) having acted on the pressure sensor 1 is less likely to be transmitted to the circuit element 130 and the pressure sensor 1.

Further, the filling section 140 can be constituted by a liquid or gel-like filler, and is particularly preferably constituted by a gel-like filler from the standpoint that an excessive displacement of the circuit element 130 and the pressure sensor 1 can be suppressed. According to such a filling section 140, the circuit element 130 and the pressure sensor 1 can be effectively protected from water, and also a pressure can be efficiently transmitted to the pressure sensor 1. The filler constituting such a filling section 140 is not particularly limited, and for example, a silicone oil, a fluorine-based oil, a silicone gel, or the like can be used.

Hereinabove, the pressure sensor module 100 has been described. Such a pressure sensor module 100 includes the pressure sensor 1 and the package 110 which houses the pressure sensor 1. Therefore, the pressure sensor 1 can be protected by the package 110. Further, the effect of the pressure sensor 1 described above can be received, and high reliability can be exhibited.

The configuration of the pressure sensor module 100 is not limited to the above-mentioned configuration, and for example, the filling section 140 may be omitted. Further, in this embodiment, the pressure sensor 1 and the circuit element 130 are supported in a state of being hung on the support substrate 120 by the bonding wires BW, however, for example, the pressure sensor 1 and the circuit element 130 maybe placed directly on the support substrate 120. Further, in this embodiment, the pressure sensor 1 and the circuit element 130 are placed side by side in the lateral direction, however, for example, the pressure sensor 1 and the circuit element 130 may be placed side by side in the height direction.

### Fourth Embodiment

Next, an electronic apparatus according to a fourth embodiment of the invention will be described.

FIG. 22 is a perspective view showing an altimeter as the electronic apparatus according to the fourth embodiment of the invention.

As shown in FIG. 22, an altimeter 200 as the electronic apparatus can be worn on the wrist like a wristwatch. In the altimeter 200, the pressure sensor 1 is mounted, and the altitude of the current location above sea level, the atmospheric pressure at the current location, or the like can be displayed on a display section 201. In this display section 201, various information such as a current time, the heart rate of a user, and weather can be displayed.

Such an altimeter 200 which is one example of the electronic apparatus includes the pressure sensor 1. Therefore, the altimeter 200 can receive the effect of the pressure sensor 1 described above and can exhibit high reliability.

### Fifth Embodiment

Next, an electronic apparatus according to a fifth embodiment of the invention will be described.

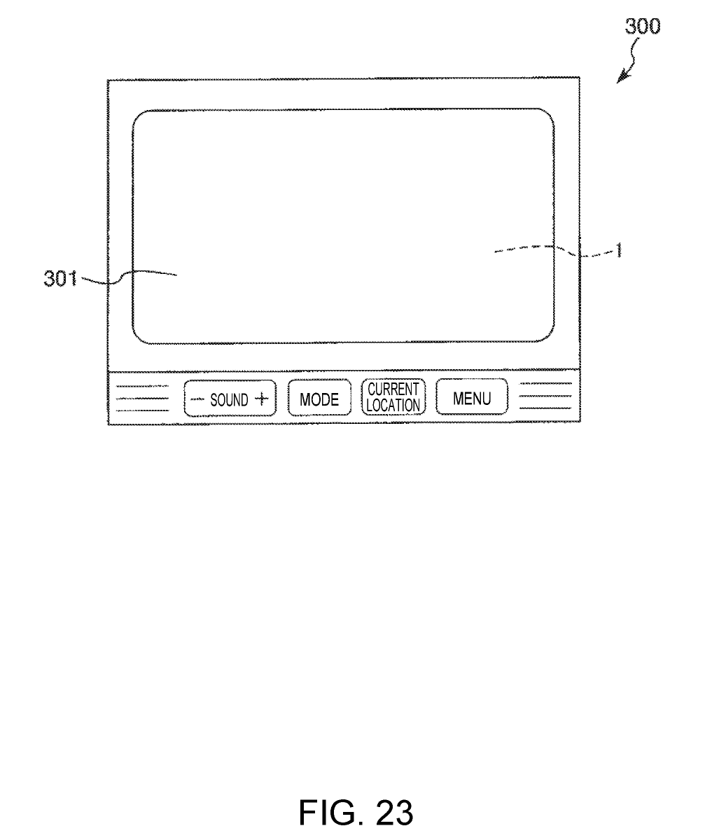

FIG. 23 is a front view showing a navigation system as the electronic apparatus according to the fifth embodiment of the invention.

As shown in FIG. 23, a navigation system 300 as the electronic apparatus includes map information (not shown), a location information acquisition unit based on a GPS (Global Positioning System), a self-contained navigation unit based on a gyroscope sensor, an accelerometer, and a vehicle speed data, the pressure sensor 1, and a display section 301 which displays given location information or route information.

According to this navigation system 300, in addition to the acquired location information, altitude information can be acquired. For example, in a case where a vehicle travels on an elevated road which is at substantially the same location as a general road in terms of location information, if altitude information is not provided, a navigation system cannot determine whether the vehicle is traveling on the general road or on the elevated road, and provides the user with information of the general road as priority information. Therefore, by mounting the pressure sensor 1 on the navigation system 300 and acquiring altitude information by the pressure sensor 1, the change in altitude due to entry into the elevated road from the general road can be detected, and the user can be provided with navigation information for the state of traveling on the elevated road.

Such a navigation system 300 as one example of the electronic apparatus includes the pressure sensor 1. Therefore, the navigation system 300 can receive the effect of the pressure sensor 1 described above and can exhibit high reliability.

The electronic apparatus according to the invention is not limited to the above-mentioned altimeter and navigation system, and can be applied to, for example, a personal computer, a digital still camera, a cellular phone, a smartphone, a tablet terminal, a timepiece (including a smart watch), a drone, medical apparatuses (for example, an electronic thermometer, a sphygmomanometer, a blood glucose meter, an electrocardiographic apparatus, an ultrasonic diagnostic apparatus, and an electronic endoscope), various types of measurement apparatuses, meters and gauges (for example, meters and gauges for vehicles, aircrafts, and ships), a flight simulator, and the like.

### Sixth Embodiment

Next, a vehicle according to a sixth embodiment of the invention will be described.

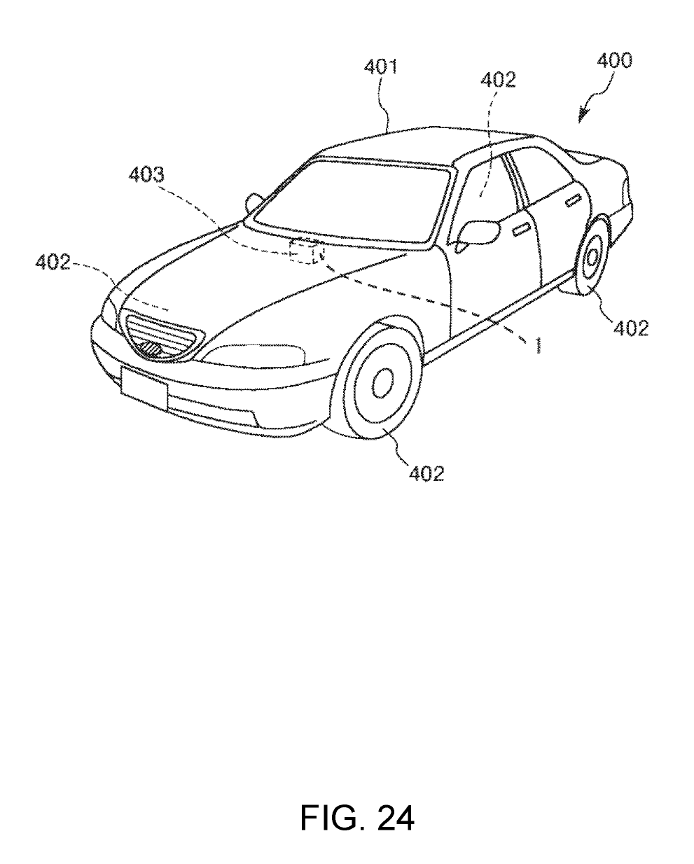

FIG. 24 is a perspective view showing a car as the vehicle according to the sixth embodiment of the invention.

As shown in FIG. 24, a car 400 as the vehicle includes a car body 401 and four wheels 402 (tires), and is configured to rotate the wheels 402 by a power source (engine) (not shown) provided in the car body 401. Further, the car 400 includes an electronic control unit (ECU) 403 mounted on the car body 401 and the pressure sensor 1 is built in this electronic control unit 403. The electronic control unit 403 ascertains the traveling state, posture, etc. of the car by detecting the acceleration, inclination, etc. of the car body 401 by the pressure sensor 1, and therefore can accurately control the wheels 402 or the like. According to this, the car 400 can safely and stably travel. The pressure sensor 1 may also be mounted on a navigation system or the like provided in the car 400.

Such a car 400 as one example of the vehicle includes the pressure sensor 1. Therefore, the car 400 can receive the effect of the pressure sensor 1 described above and can exhibit high reliability.

Hereinabove, the pressure sensor, the pressure sensor module, the electronic apparatus, and the vehicle according to the invention have been described based on the respective embodiments shown in the drawings, however, the invention is not limited thereto, and the configuration of each section can be replaced with an arbitrary configuration having the same function. Further, another arbitrary component or step may be added, and also the respective embodiments may be appropriately combined with each other.

Further, in the above-mentioned embodiments, the configuration in which the pressure reference chamber is located on the opposite side to the protective film with respect to the substrate has been described, however, the location of the pressure reference chamber is not particularly limited, and for example, the pressure reference chamber may be located on the same side as the protective film with respect to the substrate.

The entire disclosure of Japanese Patent Application No. 2017-053685, filed Mar. 17, 2017 is expressly incorporated by reference herein.

What is claimed is:

1. A pressure sensor, comprising:
a substrate which includes a diaphragm that is flexurally deformed by receiving a pressure;
a piezoresistive element which is provided in the diaphragm; and
a protective film which is provided on one surface side of the diaphragm, wherein
the protective film includes
a thin section, and
a thick section which is thicker than the thin section, and
in a plan view of the substrate,
the thin section overlaps with the piezoresistive element, and the thick section overlaps with at least a part of the diaphragm.

2. The pressure sensor according to claim 1, wherein
in a plan view of the substrate,
the thick section overlaps with at least a part of the outer edge of the diaphragm.

3. The pressure sensor according to claim 2, wherein
in a plan view of the substrate,
the outer edge of the diaphragm has at least one corner section, and
the thick section overlaps with the corner section.

4. The pressure sensor according to claim 3, wherein
in a plan view of the substrate,
the outer edge of the diaphragm has at least two corner sections and a side located between the two corner sections,
the thick section overlaps with the respective corner sections, and
the thin section overlaps with the side.

5. The pressure sensor according to claim 1, wherein the thick section overlaps with a central portion of the diaphragm.

6. The pressure sensor according to claim 1, wherein the piezoresistive element is placed in an outer edge portion of the diaphragm.

7. The pressure sensor according to claim 6, wherein the piezoresistive element is also placed in a central portion of the diaphragm.

8. The pressure sensor according to claim 1, wherein the thin section includes a first insulating film containing silicon oxide and a second insulating film containing silicon nitride.

9. The pressure sensor according to claim 1, wherein the pressure sensor includes a pressure reference chamber placed so as to overlap with the diaphragm in a plan view of the substrate.

10. A pressure sensor module, comprising:
the pressure sensor according to claim 1; and
a package which houses the pressure sensor.

11. An electronic apparatus, comprising the pressure sensor according to claim 1.

12. A vehicle, comprising the pressure sensor according to claim 1.
